(19) United States
(12) Patent Application Publication
(10) Pub. No.: US 2026/0066178 A1
(43) Pub. Date: Mar. 5, 2026

(54) TRANSFORMER COMPRISING STACKED COILS AND ELECTRONIC DEVICE COMPRISING THE SAME

(71) Applicant: SAMSUNG ELECTRONICS CO., LTD., Suwon-si (KR)

(72) Inventors: Keonwoo KIM, Suwon-si (KR); Moonyoung Kim, Suwon-si (KR); Jinhyung Lee, Suwon-si (KR); Junyoung Ko, Suwon-si (KR); Kangmoon Seo, Suwon-si (KR)

(73) Assignee: SAMSUNG ELECTRONICS CO., LTD., Suwon-si (KR)

(21) Appl. No.: 19/226,993

(22) Filed: Jun. 3, 2025

Related U.S. Application Data
(63) Continuation of application No. PCT/KR2025/007115, filed on May 26, 2025.

(30) Foreign Application Priority Data
Sep. 4, 2024 (KR) 10-2024-0119896

(51) Int. Cl. H01F 27/24; H01F 27/28; H01F 27/32; H05K 1/18

(52) U.S. Cl. CPC H01F 27/24; H01F 27/2823; H01F 27/325; H05K 1/181; H05K 2201/1003

(57) ABSTRACT

An electronic device includes: a printed circuit board (PCB); and a transformer connected to the PCB, where the transformer has a plurality of layers, the transformer including: a first planar core within a first layer; a first coil within a second layer above the first layer, the first coil including a first opening; a second planar core within the first opening and within the second layer; an isolation sheet within a third layer above the second layer; a second coil within a fourth layer above the third layer, the second coil including a second opening; a third planar core within the second opening and within the fourth layer; and a fourth planar core within a fifth layer above the fourth layer.

### CROSS-REFERENCE TO RELATED APPLICATIONS

This application is a continuation of International Application No. PCT/KR2025/007115 designating the United States, filed on May 26, 2025, in the Korean Intellectual Property Receiving Office and claiming priority to Korean Patent Application No. 10-2024-0119896, filed on Sep. 4, 2024, in the Korean Intellectual Property Office, the disclosures of each of which are incorporated by reference herein in their entireties.

### BACKGROUND

### 1. Field

This disclosure relates to a transformer including stacked coils, and an electronic device including the same.

### 2. Description of Related Art

With recent development of electronic technology, various types of display devices are being developed and distributed, and demand for large display devices is increasing. For a display device having width, height, and thickness, there is an increasing demand for a display device having the same or decreased thickness while having increased width and height to provide a wider display area. The display device may include circuit elements for processing an electrical signal. Among the circuit elements, a circuit element (e.g., a capacitor and/or an inductor) that stores energy using an electric field and/or a magnetic field may have a minimum width, height, and thickness.

The above-described information may be provided as a related art for the purpose of helping to understand the present disclosure. No claim or determination is raised as to whether any of the above-described information may be applied as a prior art related to the present disclosure.

### SUMMARY

Aspects will be set forth in part in the description which follows and, in part, will be apparent from the description, or may be learned by practice of the presented embodiments.

According to an aspect of the disclosure, an electronic device may include: a printed circuit board (PCB); and a transformer connected to the PCB, where the transformer has a plurality of layers, the transformer including: a first planar core within a first layer; a first coil within a second layer above the first layer, the first coil comprising a first opening; a second planar core within the first opening and within the second layer; an isolation sheet within a third layer above the second layer; a second coil within a fourth layer above the third layer, the second coil including a second opening; a third planar core within the second opening and within the fourth layer; and a fourth planar core within a fifth layer above the fourth layer.

According to an embodiment, an electronic device may comprise a printed circuit board (PCB), and a transformer connected to the PCB. The transformer may comprise a first layer including a first planar core. The transformer may comprise a second layer, positioned above the first layer. The second layer may comprise a first coil defining a first opening, and a second planar core positioned within the first opening. The transformer may comprise a third layer, positioned above the second layer, and including an isolation sheet. The transformer may comprise a fourth layer, positioned above the third layer. The fourth layer may comprise a second coil defining a second opening, and a third planar core positioned within the second opening. The transformer may comprise a fifth layer, positioned above the fourth layer, including a fourth planar core.

According to an embodiment, an electronic device may comprise a printed circuit board (PCB), and a transformer connected to the PCB. The transformer may comprise a first layer including a first planar core, and a second layer, positioned above the first layer. The second layer may comprise a first coil defining a first opening, and a second planar core positioned within the first opening. The transformer may comprise a third layer, positioned above the second layer, and including an isolation sheet. The transformer may comprise a fourth layer, positioned above the third layer. The fourth layer may comprise a second coil defining a second opening, and a third planar core positioned within the second opening. The transformer may comprise a fifth layer, positioned above the fourth layer, including a fourth planar core.

According to an embodiment, a transformer may comprise a bobbin including a side wall. The side wall may comprise a first portion defining a first through-hole and a second through-hole, and a second portion protruding from the first portion, to define a third through-hole that is smaller than the first through-hole and the second through-hole, and is positioned between the first through-hole and the second through-hole. The transformer may comprise a first planar core positioned within the first through-hole. The transformer may comprise a second planar core positioned within the second through-hole. The transformer may comprise a plurality of coils which are stacked on each other within the third through-hole. The transformer may comprise a ring-shaped core that is positioned within the third through-hole and is surrounding the plurality of coils.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates an electronic device according to an embodiment;

FIG. 2 illustrates exemplary power circuitry included in an electronic device according to an embodiment;

FIG. 3 illustrates an exploded perspective view of a transformer included in an electronic device according to an embodiment;

FIG. 4 illustrates a cross-sectional view of a bobbin of an electronic device according to an embodiment;

FIG. 5 illustrates a cross-sectional view of a transformer of an electronic device according to an embodiment;

FIGS. 6A and 6B illustrate a slit of a planar core included in a transformer of an electronic device according to one or more embodiments; and

FIGS. 7A and 7B illustrate a transformer disposed on a printed circuit board (PCB) of an electronic device according to one or more embodiments.

### DETAILED DESCRIPTION

Hereinafter, various embodiments of the present document will be described with reference to the accompanying drawings.

The various embodiments of the present document and terms used herein are not intended to limit the technology described in the present document to specific embodiments, and should be understood to include various modifications, equivalents, or substitutes of the corresponding embodiment. In relation to the description of the drawings, a reference numeral may be used for a similar component. A singular expression may include a plural expression unless it is clearly meant differently in the context. In the present document, an expression such as “A or B”, “at least one of A and/or B”, “A, B or C”, or “at least one of A, B and/or C”, and the like may include all possible combinations of one or more items listed together. Expressions such as “1st”, “2nd”, “first” or “second”, and the like may modify the corresponding components regardless of order or importance, is only used to distinguish one component from another component, and does not limit the corresponding components. When a (e.g., first) component is referred to as “(e.g., functionally or communicatively) connected or “accessed” to another (e.g., second) component, the component may be directly connected to the other component or may be connected through another component (e.g., a third component).

The term “module” used in the present document may include a unit configured with hardware, software, or firmware, and may be used interchangeably with terms such as logic, logic block, component, or circuit, and the like. The module may be an integrally configured component or a minimum unit or part thereof that performs one or more functions. For example, a module may be configured with an application-specific integrated circuit (ASIC).

In this document, when an expression (e.g., “on,” “at the top,” “below,” “at the bottom,” “next to”) for a positional relationship between an element and another element is mentioned, it should be understood that, unless an expression such as “rightly” or “directly,” is used, one or more intervening elements may be present therebetween, and it should be noted that the expression does not limit a positional relationship therebetween.

For example, when an element is referred to as being “above” another element, it may mean that one or more intervening elements may present therebetween, other than the element being attached to, integrally and inseparably coupled with, or integrally and inseparably formed with the other element. For example, in the present disclosure, “B disposed above A” may indicate “B disposed over A”. For example, in the present document, “B disposed above A” may indicate “B facing A and spaced apart from A”. For example, “a first planar portion disposed above the first housing part” may indicate “first planar portion in contact with the first housing part”. For example, “the first planar portion disposed above the first housing part” may indicate “the first planar portion facing the first housing part and spaced apart from the first housing part”.

For example, in this document, “B above A” may indicate “B at least partially disposed above a surface of A”. For example, in this document, “B above (or on) A” may indicate “B formed in A”. For example, in this document, “B above A” may mean “B in which a portion is formed on a surface of A and a remaining portion is formed on another surface opposite to the surface of the A”. For example, “B above A” may mean “B in which a portion is coupled to an outer surface of A and a remaining portion is coupled to an interior of the A”.

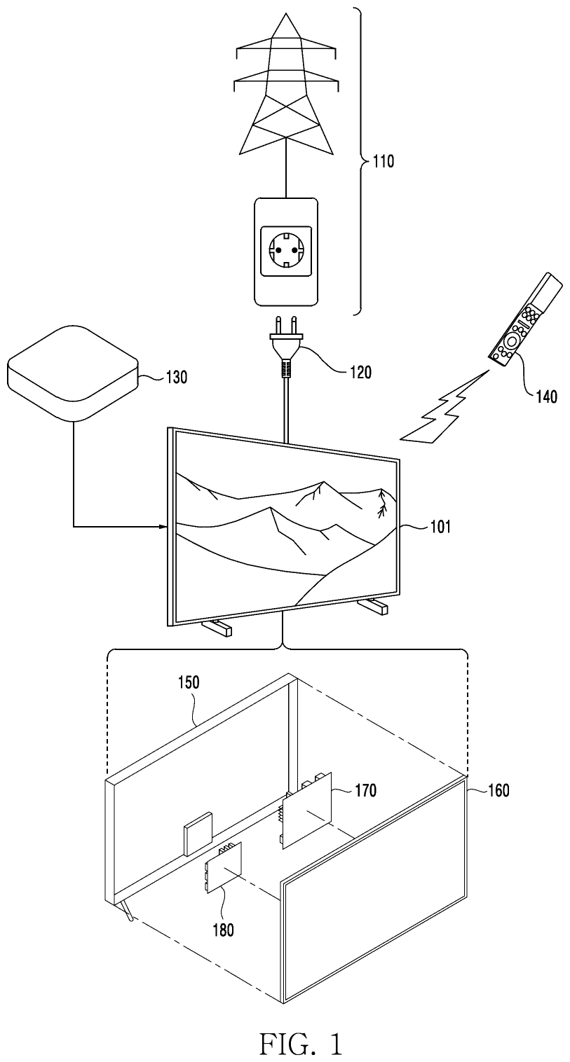

FIG. 1 illustrates an electronic device 101 according to an embodiment. The electronic device 101 may include an electronic device capable of displaying an image. For example, the electronic device 101 may include a television (TV), a monitor, a computer, a smartphone, a tablet, a portable media player, a wearable device, a video wall, an electronic frame, or the like. The electronic device 100 may include any device (e.g., a home appliance) that receives power (through a wire) from a power system 110. Hereinafter, for convenience of an explanation, a case in which the electronic device 101 is implemented as a TV is assumed and explained, but an embodiment is not limited thereto.

The electronic device 101 may be configured to operate by power (e.g., an alternate current (AC) (power) signal) provided from the power system 110. The power system 110 may be explained as an infrastructure designed to provide power to a place where the electronic device 101 is positioned. The electronic device 101 may include a plug 120 (or an electrical cord) configured to be connected to an outlet (or an outlet, a socket, a receptacle) positioned at an end of the power system 110. The plug 120 may be connected to a component (e.g., an AC-DC adapter (or an electric adapter)) of the electronic device 101 for power conversion (e.g., power conversion from the alternate current (AC) power signal to a direct current (DC) power signal).

While the plug 120 is electrically connected to the power system 110, the electronic device 101 may execute a function for outputting an image, sound, or a combination thereof (e.g., multimedia content) based on power of the power system 110. When the electronic device 101 receives information indicating an image and/or sound, the electronic device 101 may execute the function using the information. The information representing the image and/or the sound may be stored in the electronic device 101 or received from an external electronic device (e.g., a set-top box (STB)) 130 connected to the electronic device 101. The electronic device 101 may include an antenna configured to receive the information wirelessly, or may be electrically connected to the antenna.

The electronic device 101 may include hardware for receiving a user input for control of the electronic device 101 (e.g., a user input for turning on the electronic device 101 and/or a user input for adjusting a setting value of the electronic device 101 such as volume or a channel). For example, the electronic device 101 may include a switch (or a button) that is at least partially visible through a housing of the electronic device 101. For example, the electronic device 101 may include a touch sensor (e.g., a pressure sensitive touch sensor and/or a capacitive touch sensor) for detecting a touch input on at least a portion of the housing. The user input may include a direct action (e.g., an action of pressing the switch and/or the button or touching a surface of the housing) of a user for the electronic device 101. An embodiment is not limited thereto, and the user input may include an indirect action of the user related to the electronic device 101 based on a remote controller 140.

Referring to FIG. 1, the electronic device 101 may be configured to receive a wireless signal (or an optical signal) of the remote controller 140 based on infrared (IR). An embodiment is not limited thereto, and the remote controller 140 may be configured to transmit a wireless signal based on Bluetooth, Bluetooth low energy (BLE), near-field communication (NFC), ultra-wideband (UWB), wireless fidelity (WiFi), WiFi-direct, and/or another wireless short-range communication protocol, and the electronic device 101 may be configured to receive the wireless signal based on the exemplified wireless short-range communication protocol. Although the remote controller 140 dedicated to the electronic device 101 is illustrated, an embodiment of the remote controller 140 is not limited thereto. For example, the remote controller 140 may include a mobile device (e.g., an electronic device, referred to as a user terminal, a mobile phone, and/or a smartphone), in which a software application for controlling the electronic device 101 based on a wireless network is installed.

FIG. 1 includes an exploded perspective view illustrating hardware included in the electronic device 101. The electronic device 101 may include a housing 150, a display panel 160, power circuitry 170, and control circuitry 180. The housing 150 may include a rear cover (or a rear surface cover or a back cover) of the electronic device 101. The housing 150 may include an object (e.g., a support leg and/or video electronics standards association (VESA) mount holes) for supporting the electronic device 101. A surface of the electronic device 101, on which the housing 150 is visible, may be described as the rear surface (e.g., a rear side) of the electronic device 101.

Another surface of the electronic device 101, which is opposite to the surface of the electronic device 101, on which the housing 150 is visible, may be described as a front surface (e.g., a front side) of the electronic device 101. The display panel 160 may be visible from the front surface of the electronic device 101. The display panel 160 may include a liquid crystal display (LCD), a plasma display panel (PDP), and a plurality of LEDs. The LED of the display panel 160 may include an organic LED (OLED). In an embodiment, the display panel 160 may include electronic paper. When the display panel 160 has a planar shape, the display panel 160 may be referred to as a flat panel display (FPD). In case that the display panel 160 has a curved shape, the display panel 160 may be referred to as a curved display. In case that the display panel 160 has a deformable shape, the display panel 160 may be referred to as a bendable display, a flexible display, and/or a rollable display.

The control circuitry 180 may be configured to execute a function (e.g., a function to output an image, sound, or a combination thereof, a turn-on function, a turn-off function, a function adjusting volume, a function changing channels, and/or a function controlling an execution of a software application (e.g., an over the top (OTT) application) installed on the electronic device 101) of the electronic device 101 described above. For example, the control circuitry 180 may output an image and/or a video represented by the information by controlling the display panel 160 using information received from the external electronic device 130. The power circuitry 170 may be configured to provide power to the control circuitry 180. The power circuitry 170 may be configured to convert the alternate current signal received from the power system 110 into the direct current (DC) signal for driving the control circuitry 180. The power circuitry 170 may have a structure based on a switching mode power supply (SMPS).

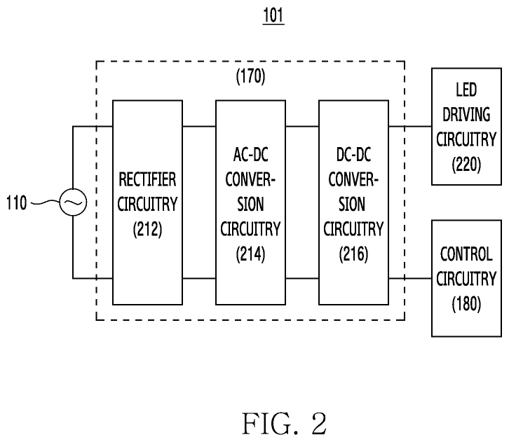

In order to obtain a DC signal from an AC signal, the power circuitry 170 may include circuit elements such as a capacitor and/or an inductor. An exemplary structure of the power circuitry 170 will be described with reference to FIG. 2. The power circuitry 170 may (substantially simultaneously) output the DC signals having various voltages to drive electronic components of the control circuitry 180 and/or the display panel 160. The power circuitry 170 may include a transformer (or a power converter) for generating the DC signals. The transformer may be described as a circuit element for transmitting electrical energy using an electromagnetic field. The transformer may occupy a physical space to form the electromagnetic field. For example, dimensions (e.g., width, height, and/or thickness) of the transformer may be dependent on a size of the electrical energy to be transmitted using the transformer. In other words, the dimensions of the transformer and the power circuitry 170 including the transformer may be determined according to power consumption of the electronic device 101 (or electronic components included in the electronic device 101, such as the display panel 160 and/or the control circuitry 180).

Demand for the electronic device 101 including the display panel 160 has led to an increase in the width and/or height of the display panel 160. That is, a consumer wants to view a screen of a wider size through the electronic device 101. On the other hand, the consumer wants the electronic device 101 to occupy less space. That is, a method of reducing the thickness of the electronic device 101 may be required. In order to decrease the thickness of the electronic device 101, a method of reducing a size of a circuit element occupying an actual space in the electronic device 101, such as a transformer of the power circuitry 170, may be required.

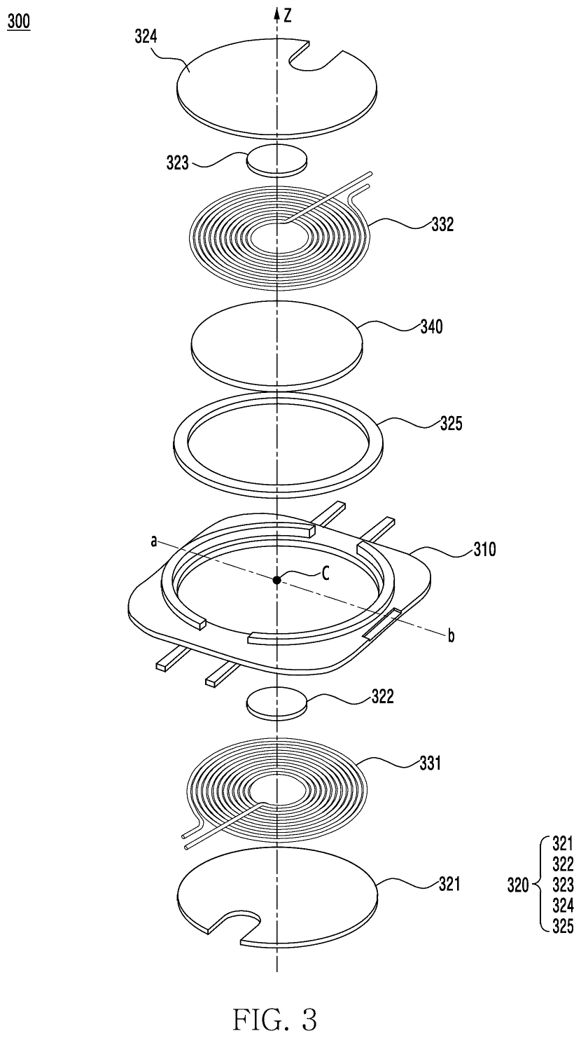

According to an embodiment, the electronic device 101 may include a transformer having performance as another transformer (substantially the same) while occupying a relatively small space. Referring to FIGS. 3 to 5, 6A, 6B, 7A, and/or 7B, an exemplary structure of a transformer included in the electronic device 101 will be described. The thickness of the electronic device 101 may be decreased by using the transformer.

FIG. 2 illustrates exemplary power circuitry 170 included in an electronic device 101 according to an embodiment. Referring to FIG. 2, circuitries included in the power circuitry 170 of the electronic device 101 of FIG. 1 are schematically illustrated.

Referring to FIG. 2, LED driving circuitry 220 and control circuitry 180 are illustrated as exemplary electronic components of the electronic device 101 connected to the power circuitry 170. The control circuitry 180 of FIG. 2 may correspond to the control circuitry 180 of FIG. 1. The LED driving circuitry 220 of FIG. 2 may be included in the display panel 160 of FIG. 1. The LED driving circuitry 220 may include a circuit for driving a light source of a display panel, referred to as a backlight. For example, the LED driving circuitry 220 may maintain or change brightness (or luminance) of a plurality of LEDs (e.g., LEDs included in a backlight component) included in the electronic device 101. For example, the LED driving circuitry 220 may generate or change voltages and/or currents applied to each of the plurality of LEDs. The voltages and/or the currents may be determined by the control circuitry 180.

Referring to FIG. 2, when receiving an AC signal (e.g., when receiving the AC signal from a power system 110), the power circuitry 170 may include rectifier circuitry 212 configured to rectify the AC signal, AC-DC conversion circuitry 214, and/or DC-DC conversion circuitry (e.g., inductor-inductor-capacitor (LLC) conversion circuitry) 216. The power circuitry 170 may further include at least one of a lightning protection circuit, a varistor, a surge arrester, and/or an electromagnetic interference (EMI) filter.

The rectifier circuitry 212 of the power circuitry 170 may output the rectified AC signal by rectifying the AC signal provided by the power system 110. In order to rectify the AC signal, the rectifier circuitry 212 may include a plurality of diodes connected in a bridge structure. Half-wave rectification or full-wave rectification based on the plurality of diodes may be performed by the rectifier circuitry 212. An embodiment is not limited thereto, and the rectifier circuitry 212 may be replaced with other rectifier circuitry implemented (or designed) in a non-bridge manner.

The AC-DC conversion circuitry 214 of the power circuitry 170 may be configured to output a DC signal from an AC signal rectified by the rectifier circuitry 212. For example, the AC-DC conversion circuitry 214 may include a capacitor charged by a rectified AC signal. For example, the AC-DC conversion circuitry 214 may be configured to control charging of the capacitor based on the rectified AC signal by changing or controlling phase of current of the rectified AC signal. The capacitor may be a circuit element storing electrical energy based on an electric field. For example, the capacitor may include an electrolytic capacitor, a tantalum capacitor, a ceramic capacitor, and/or a film capacitor. A capacitor of the AC-DC conversion circuitry 214 may be referred to as a bulk capacitor and/or a super capacitor. When the capacitor is charged by the rectified AC signal, voltage between both ends of the capacitor may be smoothen.

The AC-DC conversion circuitry 214 of the power circuitry 170 may be configured to control charging of a capacitor based on the AC signal transmitted to the electronic device 101 based on a power factor (PF). An amount of electrical energy provided from the power system 110 to the electronic device 101 for driving the electronic device 101 may be referred to as apparent power. The apparent power may be a combination of active power (or consumption power) and reactive power. In a case in which the power system 110 supplies electrical energy to electronic devices having the same active power, in case that the reactive powers of the electronic devices are different, the apparent power supplied from the power system 110 to each of the electronic devices may be different. For example, as the reactive power is higher, the apparent power is higher. A power factor means a ratio between active power and apparent power. In order to decrease a load for the power system 110, it may be required (e.g., legally) that the electronic device 101 has a power factor higher than a critical power factor. The AC-DC conversion circuitry 214 may control charging of the capacitor so that the power factor of the electronic device 101 is maintained higher than or equal to the critical power factor.

In an embodiment, the power circuitry 170 may include the DC-DC conversion circuit 216 configured to output DC signals to each of electronic components (e.g., the LED driving circuitry 220 and/or the control circuitry 180) of the electronic device 101 using electrical energy stored in a capacitor included in the AC-DC conversion circuitry 214. The DC-DC conversion circuitry 216 may generate an AC signal using the electrical energy stored in the capacitor. For example, the DC-DC conversion circuitry 216 may include an LLC conversion circuitry (or other inverter circuitry) configured to generate the AC signal using electrical energy stored in the capacitor. The AC signal generated by the DC-DC conversion circuitry 216 may be transmitted to rectifier circuitries connected to each of the LED driving circuitry 220 and the control circuitry 180 through a transformer. Each of the rectifier circuitries receiving the AC signal induced by the transformer may generate or output a DC signal having voltage required to drive a corresponding electronic component (e.g., the LED driving circuitry 220 and/or the control circuitry 180). Hereinafter, an exemplary structure of a transformer included in the DC-DC conversion circuitry 216 of the power circuitry 170 will be described with reference to FIG. 3.

FIG. 3 illustrates an exploded perspective view of a transformer 300 included in an electronic device according to an embodiment. The electronic device 101 of FIG. 1 and/or FIG. 2 may include the transformer 300 described with reference to FIG. 3. The transformer 300 of FIG. 3 may be included in the power circuitry 170 of FIGS. 1 to 2 and/or the DC-DC conversion circuitry 216 of FIG. 2.

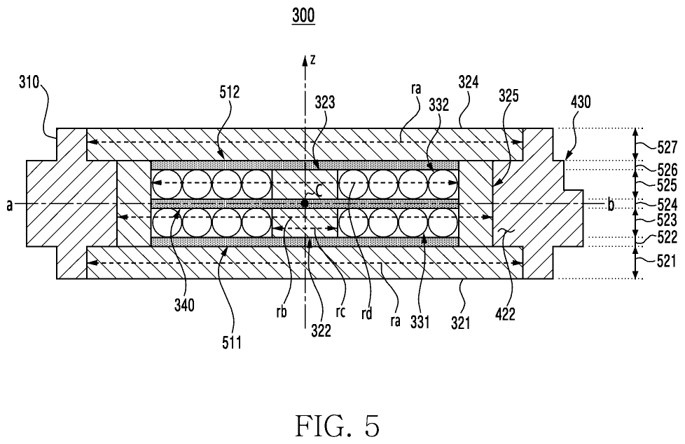

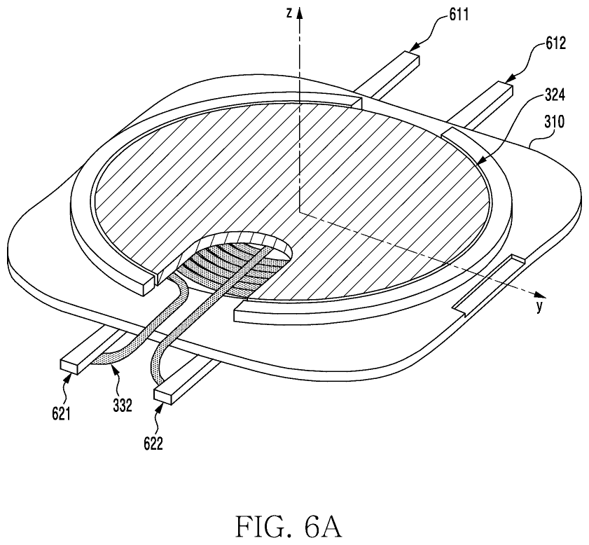

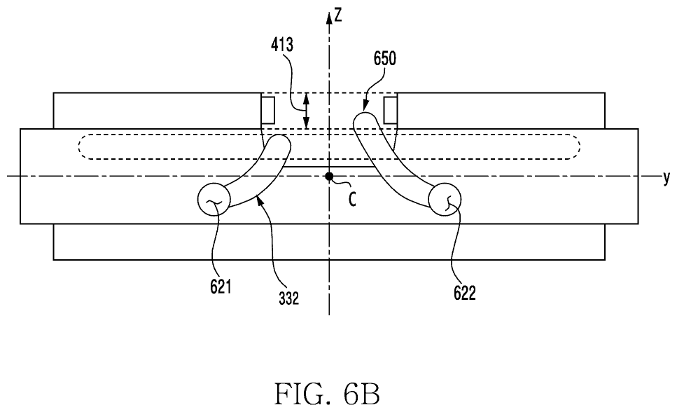

Referring to FIG. 3, the exploded perspective view in which elements of the transformer 300 are listed along a z-axis is illustrated. An exemplary structure of the transformer 300 including the elements of FIG. 3 will be described with reference to FIG. 5. An exemplary appearance (or an exterior) of the transformer 300 of FIG. 3 will be described with reference to FIGS. 6A and/or 6B.

Referring to FIG. 3, the transformer 300 may include a plurality of cores 320. The cores 320 may include a first planar core 321, a second planar core 322, a third planar core 323, a fourth planar core 324, and a ring-shaped core 325. The cores 320 may be a ferrite core including at least one of MnZn ferrite or NiZn ferrite. Such as in EE core (e.g, a core in a shape of an ‘E’), a yield of a core including a middle leg and an outer leg may be decreased, since cracks occur when height (or thickness) of the middle leg and/or the outer leg decreases. Referring to FIG. 3, since a plurality of cores 320 have a planar structure that does not include the middle leg and/or the outer leg, the plurality of cores 320 may be produced in accordance with a relatively high yield while having a relatively thin thickness. For example, the plurality of cores 320 may be stably produced without increasing a ratio of a material (e.g., a material for increasing hardness of the plurality of cores 320) distinguished from ferrite in order to improve the yield. In case that the ratio of the material is increased, a performance index of a core such as permeability may decrease. According to an embodiment, since the transformer 300 includes the plurality of cores 320 having a relatively simple shape, the transformer 300 may be (stably) produced without decreasing the permeability according to an increase in the ratio of the material.

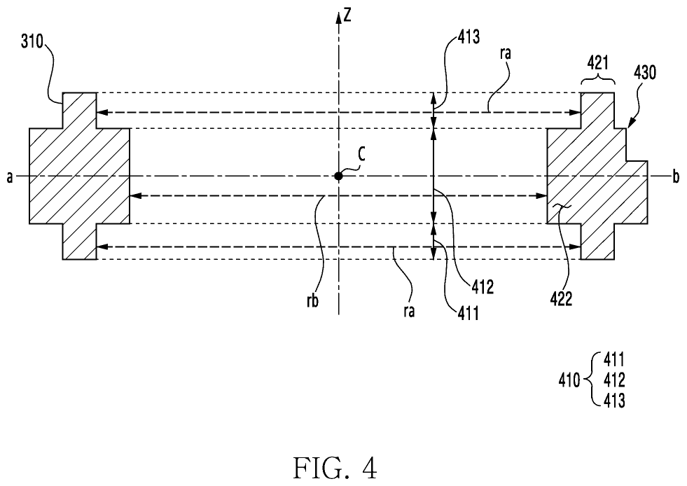

Referring to FIG. 3, the transformer 300 may include a bobbin 310. The bobbin 310 may include at least one of plastic such as bakelite or ceramic. The bobbin 310 may include a side wall surrounding at least one of the plurality of cores 320. For example, the side wall of the bobbin 310 may surround the ring-shaped core 325. The bobbin 310 may have a ring-shaped structure surrounding a side surface (e.g., a surface of the cores 320 perpendicular to the z-axis) of the plurality of cores 320. A structure of the bobbin 310 will be described with reference to FIG. 4. A positional relationship between the bobbin 310 and members of the transformer 300 will be described with reference to FIG. 5.

Referring to FIG. 3, the transformer 300 may include a plurality of coils (e.g., a first coil 331 and a second coil 332), which are wires based on a conductive material. For example, the plurality of coils may include an insulating wire (e.g., a litz wire). For example, the plurality of coils may include a USTC wire. For example, the plurality of coils may include a triple insulating wire. The plurality of coils including the insulating wire may be electrically insulated from the plurality of cores 320 by an insulating characteristic of the insulating wire. An embodiment is not limited thereto, and any one of a plurality of coils (e.g., secondary coil) may not be insulated and may be electrically connected to any one of the plurality of cores 320. The transformer 300 may include an isolation sheet 340 for the electrical insulation between the plurality of coils. The isolation sheet 340 may be referred to as an isolation sheet, an insulating film, and/or an insulating tape. Referring to FIG. 3, the first coil 331, the isolation sheet 340, and the second coil 332 may be sequentially stacked along the z-axis. For example, the first coil 331 may be positioned below (or adjacent to a surface of the isolation sheet 340) the isolation sheet 340, and the second coil 332 may be positioned above (or adjacent to another surface of the isolation sheet 340) the isolation sheet 340.

Referring to FIG. 3, members of the transformer 300 except for the bobbin 310 may be stacked along a direction of the z-axis. For example, the ring-shaped core 325, the first coil 331, and/or the second planar core 322 may be positioned above the first planar core 321. The isolation sheet 340 may be positioned above the first coil 331 and the second planar core 322. The second coil 332 and/or the third planar core 323 may be positioned above the isolation sheet 340. The fourth planar core 324 may be positioned above the ring-shaped core 325, the second coil 332, and/or the third planar core 323. An adhesive may be positioned or filled between the members of the transformer 300.

The members included in the transformer 300 may be aligned along the z-axis. For example, when looking at the transformer 300 along the z-axis, the plurality of cores 320 may be concentrically aligned. For example among the plurality of cores 320, at least two (e.g., the second planar core 322 and the third planar core 323, or the first planar core 321 and the fourth planar core 324) of the first planar core 321 to the fourth planar core 324 may overlap each other when viewing the transformer 300 along the direction (e.g., a direction perpendicular to a surface of the first planar core 321) of the z-axis. For example, when the transformer 300 is viewed along the z-axis, the first coil 331 and the second coil 332 may overlap each other. Since the first coil 331 and the second coil 332 are concentrically aligned, leakage magnetic flux of the first coil 331 and the second coil 332 may be decreased or minimized.

In order to align the members of the transformer 300, the bobbin 310 having a shape surrounding the remaining members may be designed. Hereinafter, an exemplary structure of the bobbin 310 including a through hole for accommodating the remaining members of the transformer 300 will be described with reference to FIG. 4.

FIG. 4 illustrates a cross-sectional view of a bobbin 310 of an electronic device according to an embodiment. The transformer 300 of FIG. 3 may include the bobbin 310 of FIG. 4. Referring to FIG. 4, a cross-sectional view of the bobbin 310 for line a-b of FIG. 3 is illustrated. Referring to FIG. 4, a through hole 410 formed along a z-axis may be formed or defined by the bobbin 310. The through hole 410 may extend in a straight line along a direction of the z-axis in the bobbin 310. A surface of the through hole 410 perpendicular to the z-axis may be referred to as a cross-section of the through hole 410. A size of the cross-sectional surface of the through hole 410 may include width, height, a radius, and/or a diameter of the cross-sectional surface.

Referring to FIG. 4, an embodiment in which the cross-sectional surface of the through hole 410 has a circular shape is illustrated. A shape of the through hole 410 and/or the bobbin 310 is not limited to an embodiment of FIG. 4. The through hole 410 of the bobbin 310 may have a shape and/or dimensions for accommodating members (e.g., the plurality of cores 320, the first coil 331, the second coil 332, and/or the isolation sheet 340 of FIG. 3) of a transformer (e.g., the transformer 300 of FIG. 3) including the bobbin 310. The through hole 410 of the bobbin 310 may be formed to fit the members.

Referring to FIG. 4, the through hole 410 may be divided into a first portion 411, a second portion 412, and a third portion 413 according to a size of a cross-sectional surface. Each of the first portion 411, the second portion 412, and the third portion 413 may be referred to as a first through hole, a second through hole, and a third through hole. For example, the second through hole may connect the first through hole and the third through hole. Sizes of portions (e.g., the first portion 411 to the third portion 413) of the through hole 410 may be determined to accommodate the members of the transformer.

Referring to FIG. 4, the bobbin 310 may include a side wall 421 defining each of the first portion 411 and the third portion 413 of the through hole 410, and a protruding portion 422 protruding from the side wall 421 and defining the second portion 412. The protruding portion 422 may be referred to as a side wall defining the second portion 412. In an embodiment in which the cross-sectional surface of the through hole 410 has a circular shape, a diameter (ra) of the first portion 411 and the third portion 413 may be greater than a diameter (rb) of the second portion 412. For example, a size of the second portion 412 (or the second through hole) of the through hole 410 may be smaller than sizes of the first portion 411 (or the first through hole) and the third portion 413 (or the third through hole) of the through hole 410.

In an embodiment, the members of the transformer may be positioned within the portions (e.g., the first portion 411 to the third portion 413) of the through hole 410, respectively. For example, the first portion 411 may correspond to a size (e.g., the diameter (ra) of the first planar core 321) of the first planar core 321, among the members of the transformer 300 of FIG. 3. For example, the third portion 413 may have a size (e.g., the diameter (ra) of the fourth planar core 324) of the fourth planar core 324, among the members of the transformer 300 of FIG. 3. Since the first portion 411 and the third portion 413 correspond to the lowermost member (e.g., the first planar core 321 of FIG. 3) and the uppermost member (e.g., the fourth planar core 324 of FIG. 3) of the stacked members of the transformer 300, remaining members of the transformer 300 may be positioned within the second portion 412 between the first portion 411 and the third portion 413. For example, the second portion 412 may have a size (e.g., an outer diameter (rb) of the ring-shaped core 325) of the ring-shaped core 325 of FIG. 3. For example, the second portion 412 may have a height (e.g., a size in a z-axis direction) corresponding to a sum (e.g., height of the ring-shaped core 325, or a sum of heights of a first coil 331, an isolation sheet 340, and a second coil 332) of heights of the remaining members.

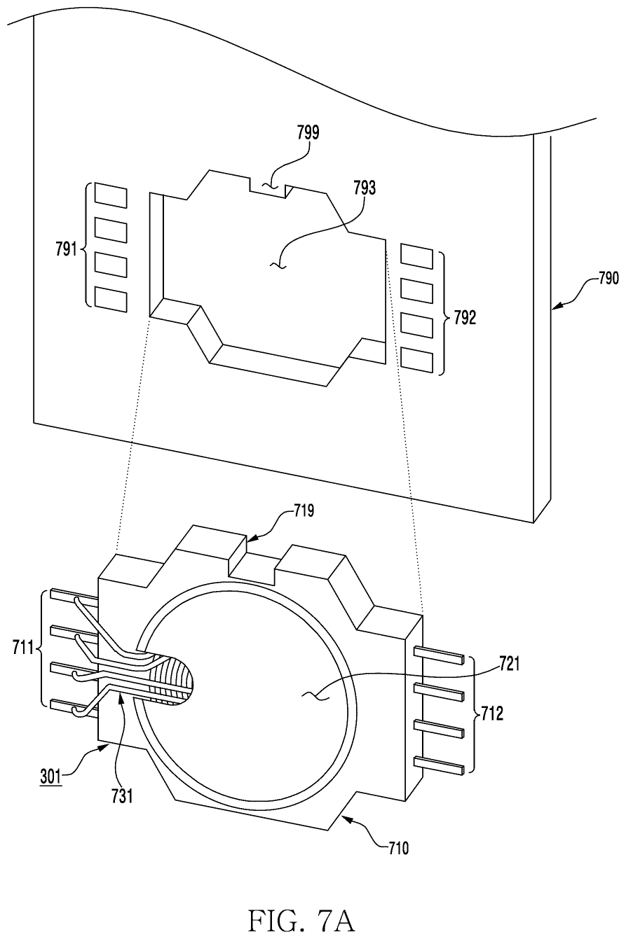

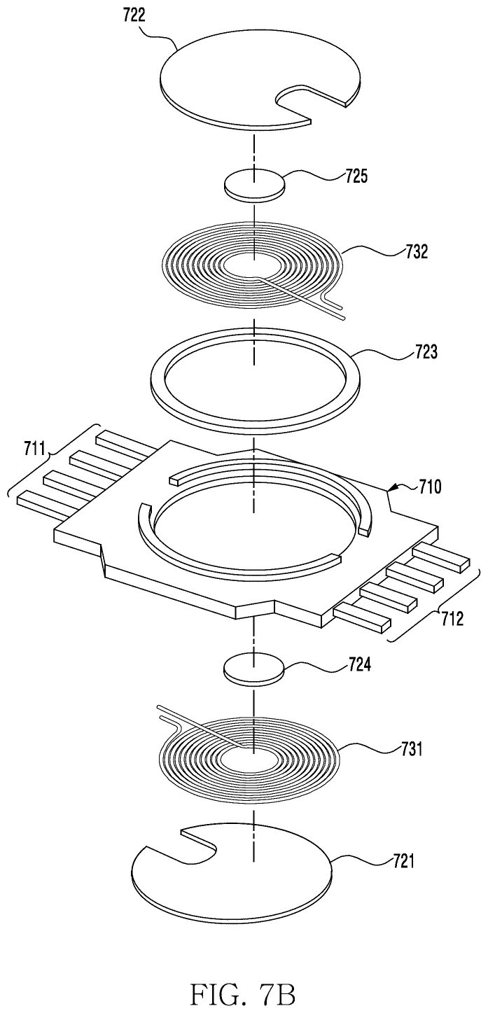

Referring to FIG. 4, the inner side of the bobbin 310 having a ring-shaped structure may have a shape and/or sizes for accommodating members of a transformer different from the bobbin 310. The outer side of the bobbin 310 may have a shape and/or sizes for coupling to a PCB (e.g., a printed circuit board) (or a PCB where the power circuitry 170 of FIG. 1 is positioned). A groove portion (or a recessed portion) 430 indicating a positional relationship between the PCB and the bobbin 310 may be formed on the outer side of the bobbin 310. The groove portion 430 may be used to determine a position and/or a direction of the bobbin 310 (or the transformer 300) with respect to the PCB in a process of coupling the bobbin 310 and the PCB. An embodiment in which the groove portion 430 guides the direction of the transformer with respect to the PCB will be described with reference to FIGS. 7A and/or 7B.

Hereinafter, referring to FIG. 5, cross-sectional surfaces of other members of the transformer positioned on the inner side of the bobbin 310 with respect to a line a-b will be illustrated together with the cross-sectional surface of the bobbin 310, illustrated with reference to FIG. 4.

FIG. 5 illustrates a cross-sectional view of a transformer 300 of an electronic device according to an embodiment. Referring to FIG. 5, the cross-sectional view of the transformer 300 cut along line a-b of FIG. 3 is illustrated. Among a description of the cross-sectional view of the transformer 300 of FIG. 5, a description that is redundant with the descriptions of FIGS. 3 to 4 may be omitted. For example, in the description of the cross-sectional view of the transformer 300 of FIG. 5, a description that is redundant with the description of the cross-sectional view of the bobbin 310 for the a-b line of FIG. 4 may be omitted.

Referring to FIG. 5, the members of the transformer 300 may be sequentially stacked inside a through hole (e.g., the through hole 410 described with reference to FIG. 4). An inner space (e.g., a cavity) of the through hole may be divided into a plurality of layers (e.g., a first layer 521 to a seventh layer 527) according to a size of the cross-sectional surface and/or a member positioned on the cross-sectional surface. The plurality of layers in which the members of the transformer 300 are positioned may include the first layer 521 including a first planar core 321. A size of the first layer 521 and/or the first planar core 321 in the first layer 521 may correspond to a size (e.g., a diameter (ra)) of the first portion 411 of the through hole 410 of FIG. 4, or may be less than or equal to the size.

Referring to FIG. 5, the plurality of layers may include a second layer 522 positioned above the first layer 521. The second layer 522 may include an isolation sheet 511 for electrically insulating the first planar core 321 and a first coil 331. The isolation sheet 511 may be omitted according to an embodiment. In an embodiment that does not include the isolation sheet 511, the first planar core 321 and the first coil 331 may be electrically connected to each other.

Referring to FIG. 5, the plurality of layers may include a third layer 523 positioned above the second layer 522. The third layer 523 may include the first coil 331 defining a first opening, and a second planar core 322 positioned within the first opening. The first opening may be formed on an inner side of an innermost coil of the first coil 331. For example, a size of the second planar core 322 may correspond to a size of the first opening (e.g., a diameter (rc)), or may be less than or equal to the size. The first coil 331 may have a form of a spiral coil wound on a two-dimensional plane (e.g., a surface formed on the third layer 523). A single turn of the spiral coil may have a polygonal shape such as a circle, a rectangle, and/or a hexagon.

Referring to FIG. 5, the plurality of layers may include a fourth layer 524 positioned above the third layer 523 and including an isolation sheet 340. The plurality of layers may include a fifth layer 525 positioned above the fourth layer 524. The fifth layer 525 may include a second coil 332 defining a second opening, and a third planar core 323 positioned within the second opening. The second opening may be formed on an inner side of an innermost coil of the second coil 332. For example, a size of the third planar core 323 may correspond to a size (e.g., the diameter (rc)) of the second opening, or may be less than or equal to the size. The second coil 332 may have a form of a spiral coil wound on a two-dimensional plane (e.g., a surface formed on the fourth layer 524). A single turn of the second coil 332 may have a polygonal shape such as a circle, a rectangle, and/or a hexagon.

Referring to FIG. 5, the plurality of layers may include a sixth layer 526 positioned above the fifth layer 525 and including an isolation sheet 512. The second layer 522 to the sixth layer 526 may be formed in the second portion 412 of the through hole 410 of FIG. 4. The ring-shaped core 325 may be disposed across the second layer 522 to the sixth layer 526, on an inner side of the bobbin 310. For example, the ring-shaped core 325 may be positioned within the second layer 522 to the sixth layer 526 and may have a structure surrounding the first coil 331 and the second coil 332. A size of the ring-shaped core 325 may correspond to a size (e.g., a diameter (rb)) of the second portion 412 of the through hole 410 of FIG. 4, or may be less than or equal to the size.

Referring to FIG. 5, the plurality of layers may include the seventh layer 527 positioned above the sixth layer 526. The seventh layer 527 may include a fourth planar core 324. A size of the seventh layer 527 and/or the fourth planar core 324 may correspond to a size (e.g., the diameter (ra)) of the third portion 413 of the through hole 410 of FIG. 4, or may be less than or equal to the size.

Referring to FIG. 5, sizes of the first planar core 321 that is the bottom of the transformer 300 and the fourth planar core 324 that is the top of the transformer 300 may be larger than sizes of other members. For example, the size (e.g., the diameter (rb)) of the ring-shaped core 325 may be smaller than the size (e.g., the diameter (ra)) of the first planar core 321. The bobbin 310 may have a shape based on sizes of the members of the transformer 300 to align the members. For example, a side wall of the bobbin 310 may have a structure enclosing the first planar core 321 in the first layer 521, the ring-shaped core 325 that accommodates members of the second layer 522 to the sixth layer 526, and the fourth planar core 324 in the seventh layer 527. Thickness of the bobbin 310 may be equal to or correspond to a sum of the thicknesses of other members (e.g., members positioned within the first layer 521 to the seventh layer 527) of the transformer 300. When the members included in the seventh layer 527 to the first layer 521 are coupled based on an adhesive, the members may be fixed within a through hole 410 of the bobbin 310. For example, the members may be fixed within the through hole by a relationship of sizes (e.g., the diameter (ra) and the diameter (rb)) of the portions of the through hole of the bobbin 310.

Referring to FIG. 5, the transformer 300 may have a multi-gap structure by the second layer 522, the fourth layer 524, and/or the sixth layer 526, where the isolation sheet is positioned. In case that thickness of planar cores wound by coils of the transformer 300 is relatively thin, one or more air gaps may be formed in the transformer 300. For example, the air gaps may be formed in the transformer 300 in case that thicknesses of planar cores (e.g., the second planar core 322 and/or the third planar core 323) wound by coils (e.g., the first coil 331 and/or the second coil 332) on a central axis (e.g., the z-axis of FIG. 5) of the transformer 300 are thinner than thicknesses of corresponding layers (e.g., the third layer 523 and/or the fifth layer 525). A multi-gap structure based on at least one air gap and/or isolation sheet(s) may cause a decrease in leakage magnetic flux of the transformer 300. Since the leakage magnetic flux is decreased, power loss in the transformer 300 may be decreased.

The number of isolation sheets positioned within the second layer 522, the fourth layer 524, and/or the sixth layer 526 may be one or more. For example, a plurality of isolation sheets may be stacked on the second layer 522. For an insulation grade and/or insulation authentication of the transformer 300 (or to enhance an insulation property), one or more isolation sheets may be positioned within at least one of the second layer 522, the fourth layer 524, or the sixth layer 526.

Referring to FIG. 5, the first coil 331 and the second coil 332 may be concentrically aligned along the z-axis. For example, the first coil 331 and the second coil 332 may be stacked on each other so that the first opening of the first coil 331 and the second opening of the second coil 332 are concentrically aligned with each other in the through hole of the bobbin 310 (e.g., in the second portion 412 of the through hole 410 of FIG. 4). Since the second planar core 322 positioned on the same plane as the first coil 331 is separated from the third planar core 323 positioned on the same plane as the second coil 332, a primary-side structure (e.g., the first coil 331 and the second planar core 322) of the transformer 300 and a secondary-side structure (e.g., the second coil 332 and the third planar core 323) of the transformer 300 may be produced independently. Furthermore, since cores of the transformer 300 have only a planar structure (e.g., the first planar core 321 to the fourth planar core 324) and a ring structure (e.g., the ring-shaped core 325), the cores may be produced at a relatively high yield, at a relatively low price, and/or relatively easily.

Referring to FIG. 5, thickness of the transformer 300 (e.g., length of the transformer 300 in the z-axis) may correspond to a sum of thicknesses of the remaining members except for the bobbin 310. For example, dimensions of the bobbin 310 may not affect the thickness of the transformer 300 or may not be included in the thickness of the transformer 300. Since the dimensions of the bobbin 310 do not affect the thickness of the transformer 300, the transformer 300 may be designed to have a relatively small thickness.

Hereinafter, exemplary shapes of a planar core (e.g., the first planar core 321 and/or the fourth planar core 324) for decreasing the thickness of the transformer 300 will be described with reference to FIG. 6A and/or FIG. 6B.

FIGS. 6A and 6B illustrate a slit of a planar core included in a transformer (e.g., the transformer 300 of FIGS. 3 to 5) of an electronic device (e.g., the electronic device 101 of FIG. 1) according to an embodiment. Referring to FIG. 6A, an exemplary view (or an appearance) of the transformer including a fourth planar core 324 and a bobbin 310 is illustrated. Although an appearance of the transformer as viewed from a +z axis is illustrated, an appearance (e.g., the appearance of the transformer in which the first planar core 321 of FIG. 3, opposite to the fourth planar core 324, is visible) of the transformer as viewed from a-z axis may also be similar to the appearance of the transformer of FIG. 6A.

Referring to FIG. 6A, a planar core (e.g., the first planar core 321 of FIGS. 3 to 5 and/or the fourth planar core 324 of FIGS. 3 to 5 and 6A) of the transformer may include a slit (or an etching portion). Referring to FIG. 6A, the slit may be overlapped or aligned on a portion where conductive wires of a coil (e.g., a second coil 332) intersect each other.

For example, the second coil 332 having a shape of a spiral coil may be wound from the outermost loop toward a rotation axis (e.g., a z-axis of FIG. 6A and/or FIG. 6B), with respect to the rotation axis. From an end of the innermost loop of the second coil 332, the conductive wire of the second coil 332 may extend across the loops of the second coil 332 to the outside of the outermost loop of the second coil 332. The second coil 332 may include an end extended from the outermost loop and an end extended from the innermost loop toward the outermost loop. Both ends of the second coil 332 may be electrically connected to pins 621 and 622 included in the bobbin 310 (or inserted into the bobbin 310), respectively. For example, the conductive wire of the second coil 332, connected to a first pin 621 of the bobbin 310, may extend toward the end of the outermost loop.

For example, the conductive wire of the second coil 332 connected to a second pin 622 of the bobbin 310 may extend across the loops of the second coil 332 toward the end of the innermost loop. Referring to FIG. 6A, since the conductive wire connected to the second pin 622 extends to the innermost loop of the loops, a portion of a conductive wire extended from the second pin 622 to the innermost loop may be overlapped with a remaining portion forming the loops of the second coil 332. Since different portions of the conductive wire overlap, thickness of the second coil 332 formed by the conductive wire may exceed the thickness of the conductive wire.

Referring to FIG. 6A, on a side surface (e.g., a first outer surface) of the bobbin 310, pins (e.g., the first pin 621 and the second pin 622) corresponding to the second coil 332 that is a secondary-side coil may be formed. Similarly, on another side surface (e.g., the side surface opposite to the side surface of the bobbin 310 where the first pin 621 and the second pin 622 are positioned) (e.g., a second outer surface opposite the first outer surface) of the bobbin 310, pins (e.g., a third pin 611 and a fourth pin 612) corresponding to the first coil 331 that is a primary-side coil, may be formed. For example, the pins 621 and 622 may be electrically connected to both ends of the second coil 332, and the pins 611 and 612 may be electrically connected to both ends of the first coil 331. The pins 611, 612, 621, and 622 may be referred to as an electrode, a connector, and/or a port to be electrically connected to another component of an electronic device (e.g., the electronic device 101 of FIGS. 1 to 2) including the transformer.

Referring to FIG. 6B, an exemplary diagram of a surface (e.g., a side surface) of a transformer with respect to a y-z plane is illustrated. The conductive wires of the second coil 332 may intersect each other in a portion 650. A slit of the fourth planar core 324, positioned within a third portion 413 of a through hole, may be overlapped on the portion 650 where different portions of the conductive wire of the second coil 332 intersect each other. Independent of an overlap of different portions of the conductive wire, based on the slit, thickness of the transformer may be determined as a sum of thicknesses of members of the transformer. For example, despite the overlap of the different portions of the conductive wire, the transformer may be designed or produced without an increase in thickness by the overlap.

For example, since a portion where the conductive wire of the second coil 332 intersects each other is overlapped with a slit of the fourth planar core 324, the portion may be seen through the slit when the transformer is viewed from the +z axis. Similarly, since a portion where a conductive wire of the first coil (e.g., the first coil 331 of FIG. 3) intersects each other is overlapped with a slit of a planar core (e.g., the first planar core 321 of FIG. 3), the portion of the first coil may be seen through the slit when viewing the transformer from the −z axis.

As described above, according to an embodiment, the transformer may have a relatively thin thickness (e.g., a slim transformer) while maintaining electrical insulation between the primary-side coil (e.g., the first coil 331 of FIG. 3) and the secondary-side coil (e.g., the second coil 332 of FIG. 3). The transformer may be produced without an increase in thickness by the bobbin 310. The planar core of the transformer may include a slit to compensate for an increase in thickness by an overlap of a conductive wire of a coil, such as in the portion 650. According to an embodiment, the transformer may be included in a switch-mode power supply (SMPS) of a TV (e.g., the electronic device 101 of FIG. 1) that requires a relatively thin thickness. According to an embodiment, the transformer may be produced with improved productivity and reliability while having the relatively thin thickness. According to an embodiment, the transformer may be applied to the SMPS (or the power circuitry 170 of FIG. 1) and/or insulating conversion circuitry.

Hereinafter, referring to FIGS. 7A and/or 7B, an exemplary structure of power circuitry (e.g., the SMPS) including the transformer described with reference to FIGS. 1 to 5 and FIGS. 6A and/or 6B will be described.

FIGS. 7A and 7B illustrate a transformer 301 disposed on a printed circuit board (PCB) 790 of an electronic device according to an embodiment. The electronic device 101 of FIGS. 1 to 2 may include the transformer 301 described with reference to FIGS. 7A and/or 7B. The power circuitry 170 of FIGS. 1 to 2 may include the PCB 790 of FIG. 7A.

Referring to FIGS. 7A and 7B, the transformer 301 including a hexagonal bobbin 710 is illustrated. The transformer 301 of FIGS. 7A and 7B may have a structure similar to that of the transformer 300 of FIGS. 3 to 5. Among a description of the transformer 301, a redundant description of the transformer 300 of FIGS. 3 to 5 may be omitted.

Referring to FIG. 7A, the transformer 301 including the bobbin 710 having a shape engaged with an opening 793 of the PCB 790 is exemplarily illustrated. For example, the bobbin 710 may have a size that is less than or equal to (a cross-sectional surface) size of the opening 793. Since the bobbin 710 is inserted into the opening 793 of the PCB 790, thickness of a circuit (e.g., the power circuitry 170 of FIG. 1) including the bobbin 710 and the PCB 790 may be smaller than a sum of thicknesses of the bobbin 710 and the PCB 790. The transformer 301 may include a plurality of coils (e.g., a first coil 731) and pins 711 and 712 electrically connected to the plurality of coils.

Referring to FIG. 7A, four pins 711 may be connected to the first coil 731. Similarly, four other pins 712 may be electrically connected to a conductive wire of another coil (e.g., a second coil 732, which will be described later with reference to FIG. 7B) different from the first coil 731. A transformer (e.g., the transformer described with reference to FIGS. 3, and 6A to 6B) having a structure in which two pins are connected to one coil (e.g., the first coil 731) and the transformer 301 having a structure in which four pins are connected to one coil have been exemplarily described, but the number of pins connected to the coil is not limited thereto.

Referring to FIG. 7A, electrodes 791 and 792 for connection with the pins 711 and 712 of the transformer 301 may be formed on the PCB 790. In a state of being inserted into the opening 793, the electrodes 791 and the pins 711 may each be electrically connected (e.g., soldered), and the electrodes 792 and the pins 712 may each be electrically connected. In an embodiment in which the first coil 731 is a primary coil of the transformer 301, in case that the pins 711 connected to the first coil 731 are connected to the electrodes 791, the electrodes 791 may be electrically connected to a DC-DC conversion circuitry (e.g., an LLC conversion circuitry of the DC-DC conversion circuitry 216 of FIG. 2). In an embodiment, in which the second coil different from the first coil 731 is a secondary coil of the transformer 301, in case that the pins 712 connected to the second coil are connected to the electrodes 792, the electrodes 792 may be electrically connected to rectifier circuitry connected to an electronic component (e.g., the LED driving circuitry 220 and/or the control circuitry 180 of FIG. 2). In the embodiment, a ratio of the number of turns of the primary coil and the secondary coil may be determined based at least on a ratio between voltage of an AC signal applied to the primary coil and voltage of a DC signal required to drive an electronic component electrically connected to the secondary coil.

Referring to FIG. 7A, the bobbin 710 of the transformer 301 may include a groove 719 formed on an outer surface thereof. The groove 719 may be formed to indicate a direction of the transformer 301 with respect to the PCB 790. Referring to FIG. 7A, the PCB 790 may include a protruding portion 799 facing an opening 793. The protruding portion 799 may have a shape that engages with the groove 719 of the bobbin 710. For example, the protruding portion 799 and the groove 719 may be formed to guide an insertion direction of the transformer 301 (completely and/or stably) facing the opening 793 of the PCB 790.

Although the groove 719 to guide the insertion direction of the transformer 301 is illustrated as an example, the insertion direction may be guided by means other than the groove 719. For example, a shape of an outer surface of the bobbin 710 may be asymmetrically designed, and a shape of the opening 793 of the PCB 790 may be designed to correspond to the shape of the asymmetric outer surface of the bobbin 710. For example, in case that the bobbin 710 may have a rectangular parallelepiped shape, which includes one right-angled corner and three rounded corners, and the opening 793 includes one right-angled corner and three rounded corners, a producer assembling the transformer 301 may insert the transformer 301 into the opening 793 along a specific insertion direction. The pins 711 and 712 and the electrodes 791 and 792 may be accurately connected by guiding the insertion direction of the transformer 301.

The insertion direction of the transformer 301 may be guided using gaps between the pins 711 and 712 and the electrodes 791 and 792. For example, in case that gaps of the pins 711 coincide with gaps of the electrodes 791, gaps of the pins 712 coincide with gaps of the electrodes 792, and the gaps of the pins 711 are different from the gaps of the pins 712, a producer of the transformer 301 may insert the transformer 301 into the opening 793 of the PCB 790 so that the pins 711 are connected to the electrodes 791, and the pins 712 are connected to the electrodes 792.

As described above with reference to FIGS. 3 to 5, and FIGS. 6A and/or 6B, the transformer 301 may include members stacked on each other in a through hole of the bobbin 710. Referring to FIG. 7B, an exploded perspective view of the transformer 301 of FIG. 7A is illustrated. The transformer 301 may include a first planar core 721. The first planar core 721 may correspond to a first layer of the transformer 301. A second layer of the transformer 301 positioned above the first layer may include the first coil 731 and a second planar core 724. The second planar core 724 may be positioned on an inner side (e.g., a first opening defined by the first coil 731) of the innermost coil of the first coil 731. The transformer 301 may include the second coil 732 and the third planar core 725. The third planar core 725 may be positioned within a second opening of the second coil 732. In an embodiment, an isolation sheet may be positioned between a third layer of the transformer 301, in which the second coil 732 and the third planar core 725 are positioned, and the second layer to provide electrical insulation between the first coil 731 and the second coil 732. A fourth layer including a fourth planar core 722 may be positioned above the third layer of the transformer 301. The transformer 301 may include a ring-shaped core 723 positioned within the second layer and the third layer and surrounding the first coil 731 and the second coil 732.

The bobbin 710 of the transformer 301 may include a through hole to accommodate remaining members (e.g., the first planar core 721, the first coil 731, the second planar core 724, the second coil 732, the third planar core 725, the fourth planar core 722, and the ring-shaped core 723) of the transformer 301 described above. The through hole may be defined by a side wall of the bobbin 710. The side wall of the bobbin 710 may have a shape enclosing the first planar core 721 in the first layer, the ring-shaped core 723 accommodating the second layer and the third layer, and the fourth planar core 722, similarly to the side wall 421 and the protruding portion 422 of FIG. 4.

Similar to an embodiment described with reference to FIGS. 4 to 5, a size of the ring-shaped core 723 may be smaller than a size of the first planar core 721 and the fourth planar core 722. In case that the side wall of the bobbin 710 has a structure enclosing the first planar core 721, the ring-shaped core 723, and the fourth planar core 722, when members of the transformer 301 are adhered to each other, the members may be fixed to each other in the through hole of the bobbin 710.

As described above, a transformer 701 including cores (e.g., the first planar core 721 to the fourth planar core 722) having a planar shape may be provided. The transformer 701 may include cores that are produced with relatively high yield and have a relatively small thickness. In order to have a decreased thickness, coils (e.g., the first coil 731 and the second coil 732) of the transformer 701 may have a structure of a spiral coil. The bobbin 710 may have a structure enclosing the cores from the outer side of the cores. Thickness of the transformer 701 may be dependent on a sum of thicknesses of remaining members except for the bobbin 710. The first planar core 721 and the fourth planar core 722 may further include a slit aligned on a portion where conductive wires of coils (e.g., the first coil 731 and the second coil 732) are overlapped. An increase in the thickness of the transformer 701, caused by the portion where the conductive wires overlap, may be decreased or prevented by the slit.

In an embodiment, a transformer having a relatively small thickness may be required. In an embodiment, a method of maintaining or increasing leakage magnetic flux of the transformer while reducing the thickness of the transformer may be required. In an embodiment, a method of simplifying a structure of a core including ferrite of the transformer may be required. As described above, according to an embodiment, an electronic device may comprise a printed circuit board (PCB) (e.g., the PCB 790 of FIG. 7A), and a transformer (e.g., the transformer 300 of FIG. 3 and/or the transformer 301 of FIG. 7A) connected to the PCB. The transformer may comprise a first layer (e.g., the first layer 521 of FIG. 5) including a first planar core (e.g., the first planar core 321 of FIG. 3 and/or the first planar core 721 of FIG. 7B). The transformer may comprise a second layer (e.g., the third layer 523 of FIG. 5), positioned above the first layer. The second layer may comprise a first coil (e.g., the first coil 331 of FIG. 3 and/or the first coil 731 of FIG. 7B) defining a first opening, and a second planar core (e.g., the second planar core 322 of FIG. 3 and/or the second planar core 724 of FIG. 7B) positioned within the first opening. The transformer may comprise a third layer (e.g., a fourth layer 524 of FIG. 5), positioned above the second layer, and including an isolation sheet (e.g., the isolation sheet 340 of FIG. 3). The transformer may comprise a fourth layer (e.g., the fifth layer 525 of FIG. 5), positioned above the third layer. The fourth layer may comprise a second coil (e.g., the second coil 332 of FIG. 3 and/or the second coil 732 of FIG. 7B) defining a second opening, and a third planar core (e.g., the third planar core 323 of FIG. 3 and/or the third planar core 725 of FIG. 7B) positioned within the second opening. The transformer may comprise a fifth layer (e.g., the seventh layer 527 of FIG. 5), positioned above the fourth layer, including a fourth planar core (e.g., the fourth planar core 324 of FIG. 3 and/or a fourth planar core 722 of FIG. 7B).

For example, the transformer may comprise a ring-shaped core (e.g., the ring-shaped core 325 of FIG. 3 and/or the ring-shaped core 723 of FIG. 7B) that is positioned within the second layer, the third layer, and the fourth layer, and is surrounding the first coil and the second coil.

For example, the transformer may comprise a bobbin (e.g., the bobbin 310 of FIG. 3 and/or the bobbin 710 of FIG. 7B) including side walls enclosing the first planar core within the first layer, the ring-shaped core accommodating the second layer, the third layer, and the fourth layer, and the fourth planar core within the fifth layer.

For example, the sidewalls of the bobbin may comprise a first side wall defining a first through-hole corresponding to the first layer, a second side wall defining a second through-hole corresponding to the fifth layer, and a third side wall defining a third through-hole corresponding to the second layer, the third layer, and the fourth layer, and connecting the first through-hole and the second through-hole.

For example, the third through-hole may be smaller than the first through-hole and the second through-hole.

For example, the bobbin may comprise a groove (e.g., the groove 719 of FIG. 7A) formed at an outer surface of at least one of the side walls to indicate a direction of the transformer with respect to the printed circuit board (PCB).

For example, the bobbin may comprise first pins (e.g., the pins 611 and 612 of FIG. 6A and/or the pins 711 of FIG. 7B) electrically connected to both ends of the first coil, and second pins (e.g., the pins 621 and 622 of FIG. 6B and/or the pins 712 of FIG. 7B) electrically connected both ends of the second coil.

For example, the first pins may be positioned, on an outer surface of at least one of the side walls, on another surface opposite to a surface where the second pins are positioned.

For example, the first planar core may comprise a slit overlapped on a portion where a conductive wire of the first coil is intersected to each other.

For example, the fourth planar core may comprise a slit overlapped on a portion where a conductive wire of the second coil is intersected to each other.

For example, the second planar core and the third planar core may be positioned, when viewing the transformer along a direction perpendicular to a surface of the first planar core, to be overlapped to each other.

For example, the isolation sheet may be a first isolation sheet, and the transformer may comprise a sixth layer (e.g., the second layer 522 of FIG. 5), positioned between the first layer and the second layer, including a second isolation sheet (e.g., the isolation sheet 511 of FIG. 5), and a seventh layer (e.g., the sixth layer 526 of FIG. 5), positioned between the fourth layer and the fifth layer, including a third isolation sheet (e.g., the isolation sheet 512 of FIG. 5).

As described above, according to an embodiment, an electronic device may comprise a printed circuit board (PCB) (e.g., the PCB 790 of FIG. 7A), and a transformer connected to the PCB. The transformer may comprise a first layer including a first planar core, and a second layer, positioned above the first layer. The second layer may comprise a first coil defining a first opening, and a second planar core positioned within the first opening. The transformer may comprise a third layer, positioned above the second layer, and including an isolation sheet. The transformer may comprise a fourth layer, positioned above the third layer. The fourth layer may comprise a second coil defining a second opening, and a third planar core positioned within the second opening. The transformer may comprise a fifth layer, positioned above the fourth layer, including a fourth planar core.

For example, the transformer may comprise a ring-shaped core that is positioned within the second layer, the third layer, and the fourth layer, and is surrounding the first coil and the second coil.

For example, the transformer may comprise a bobbin including side walls enclosing the first planar core within the first layer, the ring-shaped core accommodating the second layer, the third layer, and the fourth layer, and the fourth planar core within the fifth layer.

For example, the bobbin may have a shape to be engaged with an opening of the PCB.

As described above, according to an embodiment, a transformer may comprise a bobbin including a side wall. The side wall may comprise a first portion defining a first through-hole and a second through-hole, and a second portion protruding from the first portion, to define a third through-hole that is smaller than the first through-hole and the second through-hole, and is positioned between the first through-hole and the second through-hole. The transformer may comprise a first planar core positioned within the first through-hole. The transformer may comprise a second planar core positioned within the second through-hole. The transformer may comprise a plurality of coils which are stacked on each other within the third through-hole. The transformer may comprise a ring-shaped core that is positioned within the third through-hole and is surrounding the plurality of coils.

For example, the plurality of coils may include a first coil defining a first opening, and a second coil defining a second opening.

For example, the transformer may comprise a third planar core positioned within the first opening, and a fourth planar core positioned within the second opening.

For example, the first coil and the second coil are stacked on each other within the third through-hole such that the first opening and the second opening are concentrically aligned to each other.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

The device described above may be implemented as a hardware component, a software component, and/or a combination of a hardware component and a software component. For example, the devices and components described in the embodiments may be implemented by using one or more general purpose computers or special purpose computers, such as a processor, controller, arithmetic logic unit (ALU), digital signal processor, microcomputer, field programmable gate array (FPGA), programmable logic unit (PLU), microprocessor, or any other device capable of executing and responding to instructions. The processing device may perform an operating system (OS) and one or more software applications executed on the operating system. In addition, the processing device may access, store, manipulate, process, and generate data in response to the execution of the software. For convenience of understanding, there is a case that one processing device is described as being used, but a person who has ordinary knowledge in the relevant technical field may see that the processing device may include a plurality of processing elements and/or a plurality of types of processing elements. For example, the processing device may include a plurality of processors or one processor and one controller. In addition, another processing configuration, such as a parallel processor, is also possible.

The software may include a computer program, code, instruction, or a combination of one or more thereof, and may configure the processing device to operate as desired or may command the processing device independently or collectively. The software and/or data may be embodied in any type of machine, component, physical device, computer storage medium, or device, to be interpreted by the processing device or to provide commands or data to the processing device. The software may be distributed on network-connected computer systems and stored or executed in a distributed manner. The software and data may be stored in one or more computer-readable recording medium.

The method according to the embodiment may be implemented in the form of a program command that may be performed through various computer means and recorded on a computer-readable medium. In this case, the medium may continuously store a program executable by the computer or may temporarily store the program for execution or download. In addition, the medium may be various recording means or storage means in the form of a single or a combination of several hardware, but is not limited to a medium directly connected to a certain computer system, and may exist distributed on the network. Examples of media may include a magnetic medium such as a hard disk, floppy disk, and magnetic tape, optical recording medium such as a CD-ROM and DVD, magneto-optical medium, such as a floptical disk, and those configured to store program instructions, including ROM, RAM, flash memory, and the like. In addition, examples of other media may include recording media or storage media managed by app stores that distribute applications, sites that supply or distribute various software, servers, and the like.

As described above, although the embodiments have been described with limited examples and drawings, a person who has ordinary knowledge in the relevant technical field is capable of various modifications and transform from the above description. For example, even if the described technologies are performed in a different order from the described method, and/or the components of the described system, structure, device, circuit, and the like are coupled or combined in a different form from the described method, or replaced or substituted by other components or equivalents, appropriate a result may be achieved.

Therefore, other implementations, other embodiments, and those equivalent to the scope of the claims are in the scope of the claims described later.

What is claimed is:

1. An electronic device comprising:
a printed circuit board (PCB); and
a transformer connected to the PCB,
wherein the transformer has a plurality of layers, the transformer comprising:
a first planar core within a first layer;
a first coil within a second layer above the first layer,
the first coil comprising a first opening;
a second planar core within the first opening and within the second layer;
an isolation sheet within a third layer above the second layer;
a second coil within a fourth layer above the third layer, the second coil comprising a second opening;
a third planar core within the second opening and within the fourth layer; and
a fourth planar core within a fifth layer above the fourth layer.

2. The electronic device of claim 1, wherein the transformer further comprises:
a ring-shaped core within the second layer, the third layer, and the fourth layer, the ring-shaped core surrounding the first coil and the second coil.

3. The electronic device of claim 2, wherein the transformer further comprises:
a bobbin comprising side walls enclosing:
the first planar core within the first layer,
the ring-shaped core within the second layer, the third layer, and the fourth layer, and
the fourth planar core within the fifth layer.

4. The electronic device of claim 3, wherein the side walls of the bobbin comprise:
a first side wall enclosing a first through-hole corresponding to the first layer;
a second side wall enclosing a second through-hole corresponding to the fifth layer; and
a third side wall enclosing a third through-hole corresponding to the second layer, the third layer, and the fourth layer, the third through-hole connecting the first through-hole and the second through-hole.

5. The electronic device of claim 4, wherein the third through-hole is smaller than the first through-hole and the second through-hole.

6. The electronic device of claim 3, wherein the bobbin further comprises:
a groove on an outer surface of at least one of the side walls corresponding to an orientation of the transformer with respect to the PCB.

7. The electronic device of claim 3, wherein the bobbin further comprises:
first pins electrically connected to ends of the first coil; and
second pins electrically connected ends of the second coil.

8. The electronic device of claim 7, wherein the first pins are on a first outer surface of at least one of the side walls, and the second pins are on a second outer surface of at least one of the side walls, the first outer surface being opposite to the second outer surface.

9. The electronic device of claim 1, wherein the first planar core comprises:
a slit overlapping a position at which conductive wires of the first coil are intersecting.

10. The electronic device of claim 1, wherein the fourth planar core comprises:
a slit overlapping a position at which conductive wires of the second coil are intersecting.

11. The electronic device of claim 1, wherein, with respect to a plane corresponding to a surface of the first planar core, the second planar core and the third planar core are overlapping each other.

12. The electronic device of claim 1,
wherein the transformer further comprises:
a second isolation sheet in a sixth layer between the first layer and the second layer; and
a third isolation sheet in a seventh layer between the fourth layer and the fifth layer.

13. A transformer having a plurality of layers, the transformer comprising:
a first planar core within a first layer;
a first coil within a second layer above the first layer, the first coil comprising a first opening;
a second planar core within the first opening and within the second layer;
an isolation sheet within a third layer above the second layer;
a second coil within a fourth layer above the third layer, the second coil comprising a second opening;
a third planar core within the second opening and within the fourth layer; and
a fourth planar core within a fifth layer above the fourth layer.

14. The transformer of claim 13, further comprising:
a ring-shaped core within the second layer, the third layer, and the fourth layer, the ring-shaped core surrounding the first coil and the second coil.

15. The transformer of claim 14, further comprising:
a bobbin comprising side walls enclosing:
the first planar core within the first layer,
the ring-shaped core within the second layer, the third layer, and the fourth layer, and
the fourth planar core within the fifth layer.

16. The transformer of claim 15, wherein the bobbin has a shape that is configured to engage with an opening of a printed circuit board (PCB).

17. A transformer comprising:
a bobbin comprising a side wall, wherein the side wall comprises:
a first portion enclosing a first through-hole and a second through-hole, and
a second portion protruding from the first portion and enclosing a third through-hole that is smaller than the first through-hole and the second through-hole, the third through-hole being between the first through-hole and the second through-hole;
a first planar core within the first through-hole;
a second planar core within the second through-hole;
a plurality of coils stacked on each other within the third through-hole; and
a ring-shaped core within the third through-hole and surrounding the plurality of coils.

18. The transformer of claim 17, wherein the plurality of coils comprise:
a first coil comprising a first opening; and
a second coil comprising a second opening.

19. The transformer of claim 18, further comprising:
a third planar core within the first opening; and
a fourth planar core within the second opening.

20. The transformer of claim 18, wherein the first opening and the second opening are concentrically aligned with each other, and the first coil and the second coil are stacked on each other within the third through-hole.
